(19) United States
(12) Patent Application Publication
(10) Pub. No.: US 2026/0096180 A1
(43) Pub. Date: Apr. 2, 2026

(54) SEMICONDUCTOR DEVICES AND METHODS OF FORMING THEREOF

(71) Applicant: GlobalFoundries Singapore Pte. Ltd., Singapore (SG)

(72) Inventors: FANGYUE LIU, Singapore (SG); RUI TZE TOH, Singapore (SG); XIN CHEN, Singapore (SG)

(21) Appl. No.: 18/898,696

(22) Filed: Sep. 27, 2024

(51) Int. Cl. H10D 64/27; H01L 21/28

(52) U.S. Cl. CPC H10D 64/519; H10D 64/01326; H10D 64/518

(57) ABSTRACT

A semiconductor structure including an active region and an isolation region adjacent to the active region and a gate arranged over the active region and the isolation region is provided. A first gate contact and a second gate contact is arranged over the gate. The first gate contact overlaps the active region and the second gate contact overlaps the isolation region. A metal line extends over the first gate contact and the second gate contact.

### TECHNICAL FIELD

The present disclosure relates generally to semiconductor devices, and more particularly to structures having gate contacts over an active region and an isolation region.

### BACKGROUND

The scaling of features in integrated circuits, commonly referred to as semiconductor scaling, enables increased densities of functional units on semiconductor chips. For example, scaling leads to increased capacity as a higher number of semiconductor transistors such as memory or logic devices may be incorporated on a chip. However, scaling of features faces several challenges as technology advances. In one aspect, controlling the dimensions of components such as transistors becomes increasingly difficult. For example, variations in doping concentrations, oxide thicknesses, and other process parameters can lead to inconsistent device performance and yield issues. Process limitations, for example, in lithographic processes used for patterning features and deposition processes also present significant challenges as feature sizes decrease. In some cases, defective dies may be formed during fabrication of the semiconductor devices. Further, as feature sizes scale down, the resistance and capacitance of interconnects become more significant, which may limit the speed at which signals can travel across the chip. Accordingly, it is desirable to provide improved semiconductor structures and methods of forming semiconductor devices.

### SUMMARY

According to various embodiments, a semiconductor structure including an active region and an isolation region adjacent to the active region is provided. A gate is arranged over the active region and the isolation region. A first gate contact and a second gate contact is arranged over the gate. The first gate contact overlaps the active region and the second gate contact overlaps the isolation region. A metal line extends over the first gate contact and the second gate contact.

According to another aspect, a method of forming a structure is provided. The method includes forming a gate over an active region and an isolation region, and forming a first gate contact and a second gate contact over the gate. The first gate contact overlaps the active region and the second gate contact overlaps the isolation region. The method may further include forming a metal line over the first gate contact and the second gate contact.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following:

FIGS. 1A-1B illustrate top views of an embodiment of a structure;

FIGS. 1C-1D illustrate side views of embodiments of the structure taken along line A-A′ in FIG. 1B;

FIGS. 2A-2B illustrate top views of an embodiment of a structure; and

FIGS. 3A-3C show cross-sectional views of a process for forming a structure.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the embodiments. Other embodiments may be utilized and structural, logical, and electrical changes may be made without departing from the scope of the invention. The various embodiments are not necessarily mutually exclusive, as some embodiments can be combined with one or more other embodiments to form new embodiments.

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

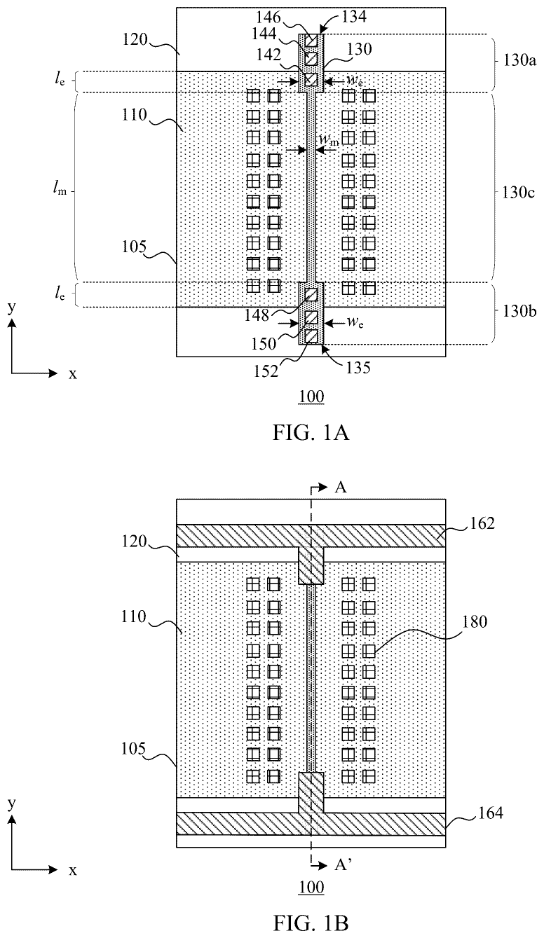

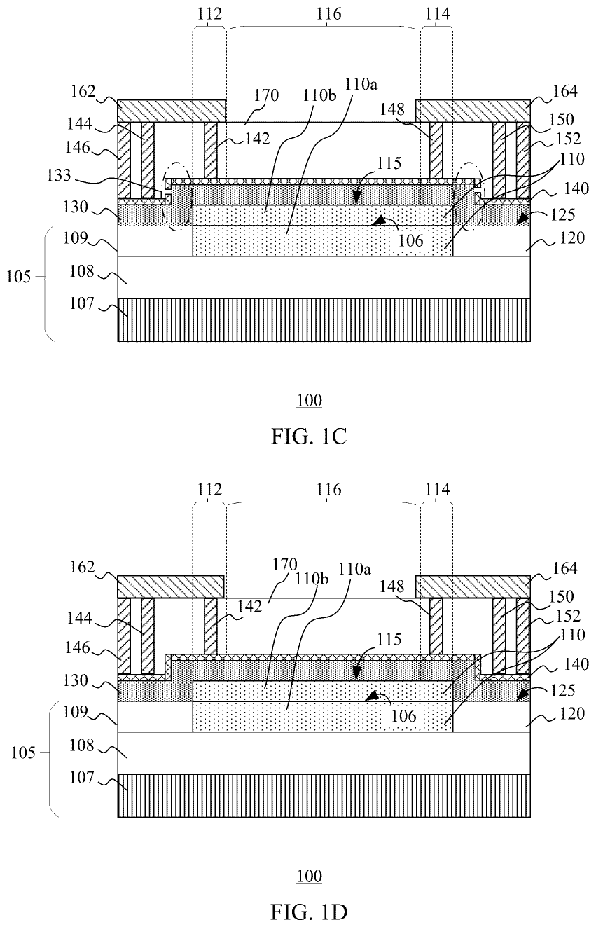

FIGS. 1A-1B illustrate top views of an embodiment of a structure 100, while FIGS. 1C-1D illustrate side views of embodiments of the structure 100 taken along line A-A′ in FIG. 1B. The device, for example, may be a metal oxide semiconductor field effect transistor (MOSFET), such as an extended drain MOSFET (EDMOS). The structure 100, for example, may be used in RF applications. Referring to FIGS. 1A-1D, the structure 100 may include a substrate 105. The substrate 105 may be a semiconductor substrate, such as a bulk semiconductor substrate or crystalline-on-insulator (COI) substrate. For example, the substrate 105 may be a bulk silicon substrate or a silicon-on-insulator (SOI) substrate. In the case of a COI substrate, the substrate 105 for example, may include a base semiconductor layer 107, a buried insulating layer 108 on the base semiconductor layer 107, and a semiconductor material layer 109 on the buried insulating layer 108. An active region 110a may be arranged in the substrate 105. In one embodiment, a raised active region portion 110b may be arranged directly on the substrate 105, as illustrated in FIG. 1C. The raised active region portion 110b may be arranged directly on the active region 110a in the substrate 105. The raised active region portion 110b may be an epitaxially grown portion of the active region 110. The active region 110a and the raised active region portion 110b may collectively form the active region 110 of the structure 100. In other words, the active region 110 may include a portion 110a arranged within the substrate 105 (e.g., substrate portion), and a raised portion 110b formed directly on the substrate 105 (e.g., epitaxially grown portion). The raised active region portion 110b creates a step height of the active region 110 with respect to an adjacent isolation region 120. The raised active region portion 110b, for example, may be formed by a selective epitaxy process that deposits a single crystalline semiconductor material (e.g., silicon, germanium, silicon-germanium alloy) directly on a top surface 106 of the substrate 105 and in epitaxial alignment with the active region 110a within the substrate 105 (e.g., epitaxially grown). The semiconductor material of the epitaxially grown portion may be the same as the material of the underlying semiconductor material layer of the substrate on which it is grown. Electrical dopants may be implanted into the deposited single crystalline semiconductor material and the underlying portion of the substrate to form the active region 110 the structure 100. Referring to FIG. 1C, the active region 110 may have edge portions 112 and 114, and an inner portion 116 between the edge portions 112 and 114. Edge portions 112 and 114 of the active region 110 may surround the inner portion 116 of the active region 110. The active region 110 may include source and drain regions of the device. The isolation region 120 may be disposed in the substrate 105 and may be adjacent to the active region 110a in the substrate 105. The edge portions 112 and 114 of the active region 110 may be nearest to the isolation region 120 compared to the inner portion 116 of the active region 110. The isolation region 120, for example, may be a shallow trench isolation (STI) region. The isolation region 120 may be formed of a dielectric material, such as silicon oxide for example. In one embodiment, the isolation region 120 may abut the active region 110a in the substrate 105. The isolation region 120 may surround the active region 110a in the substrate 105.

A gate 130 may be arranged over the substrate 105. The gate 130 may be a gate electrode of a gate structure and formed of a conductive material, such as polysilicon for example. The gate 130 may overlie a gate dielectric over the substrate 105 (gate dielectric not shown). The gate structure, for example, may further include a dielectric gate spacer around the gate 130 (not shown). The gate 130 may be arranged over the active region 110 and the isolation region 120. The gate 130 may extend lengthwise over the active region 110 in a first direction (e.g., y-direction) and between the source region and the drain region. In one embodiment, the gate 130 may follow the contours of the underlying active region 110 and isolation region 120. A portion of the gate 130 may be conformal to a top surface 115 of the raised active region portion 110b of the active region 110 and another portion of the gate 130 may be conformal to a top surface 125 of the isolation region 120, forming a stepped profile 133 of the gate 130, as illustrated in FIG. 1C. The term “conformal” may refer to when a material layer conforms to or follows the contours of the surface that the material layer is in direct contact with. A lateral or top surface of the gate 130 may include two different planes that are parallel but vertically spaced apart from one another, and an interposing plane extending between the two different planes, forming the stepped profile. Although FIGS. 1C and 1D illustrate the stepped profile 133 of the gate 130 as having right angles, it is understood that the stepped profile 133 may be sloped.

Referring to FIG. 1A, the gate 130 may include gate end portions 130a and 130b, and a gate middle portion 130c between the gate end portions 130a and 130b. The gate end portions 130a and 130b may include opposing edges 134 and 135 of the gate 130, respectively. Referring to FIGS. 1A and 1C, the gate end portion 130a of the gate 130 may overlap an edge portion 112 of the active region 110 and the isolation region 120. The gate end portion 130b of the gate 130 may overlap an edge portion 114 of the active region 110 and the isolation region 120. The gate middle portion 130c of the gate 130 may overlap the inner portion 116 of the active region 110. In one embodiment, the gate end portions 130a and 130b of the gate 130 are wider than the gate middle portion 130c of the gate 130. The gate end portions 130a and 130b may each have a gate width we which is greater than a gate width Wm of the gate middle portion 130c of the gate 130. The gate width may be taken in the second direction (e.g., x-direction). The second direction may be perpendicular to the first direction. The gate end portions 130a and 130b of the gate 130 are configured to accommodate landing of gate contacts and are wider or laterally thicker than the gate middle portion 130c. The gate middle portion 130c may be narrower or having a lateral thickness (e.g., in the x-direction) less than the gate end portions 130a and 130b, advantageously providing a low average gate width or lateral thickness of the gate 130 (or lower average gate width compared to a case where the gate width wm of the gate middle portion 130c is the same as the gate width we of the gate end portions 130a and 130b). The average gate width of a gate may have an inverse relation to the device performance of a transistor, such as fₜ or fₘₐₓ of the transistor. fₜ, for example, is the transition frequency of the transistor where transistor current gain goes to unity or zero dB. fₘₐₓ, for example, may be the frequency where unilateral gain (U) or power gain becomes unity, or zero dB. For example, in another case where the gate width or lateral thickness (e.g., in the x-direction) of the gate 130 is configured to accommodate landing of gate contacts and is the same or uniform across the entire gate length (e.g., in the y-direction) from edge 134 to edge 135 of the gate 130, the average gate width or lateral thickness of the gate 130 may be increased significantly or to a significantly greater extent, providing a high average gate width which causes fₜ drop of a transistor. fₜ drop of the transistor may further cause fₘₐₓ of the transistor to drop. Accordingly, by providing wider gate end portions 130a and 130b so as to accommodate landing of gate contacts while having the gate middle portion 130c narrower than the gate end portions 130a and 130b, the average gate width of the gate 130 is not significantly increased, thus avoiding the penalty of fₜ drop of the transistor. Further, the device performance may be dominated by the narrower gate width wₘ of the gate middle portion 130c as the gate end portions 130a and 130b represent a small fraction of the gate length of the gate 130 over the active region 110. For example, a sum of gate length lₑ of both the gate end portions 130a and 130b over the active region 110 may be less than 20% of a sum of gate length lₘ of the gate middle portion 130c and gate length lₑ of both the gate end portions 130a and 130b over the active region 110.

Referring to FIG. 1C, a silicide layer 140 may be arranged over the gate 130. The silicide layer 140 may be formed of a metal silicide material such as NiSi, PtSi, or TiSi. In some embodiments, the silicide layer 140 may be discontinuous. For example, the silicide layer 140 may be disposed over the gate 130 with silicide layer breakage, such as at or near where the silicide layer 140 coincides with the stepped profile 133 of the underlying gate 130. In other embodiments, the silicide layer 140 may be a continuous layer, as illustrated in FIG. 1D. For example, the silicide layer 140 may be disposed over the gate 130 without breakage.

Gate contacts 142, 144, 146, 148, 150 and 152 may be arranged over the gate 130. The gate contacts 142, 144 and 146 may be positioned over the gate end portion 130a of the gate 130. In one embodiment, the gate contact 142 may overlap the active region 110, while gate contacts 144 and 146 may overlap the isolation region 120. The gate contacts 148, 150 and 152 may be positioned over the gate end portion 130b of the gate 130. In one embodiment, the gate contact 148 may overlap the active region 110, while gate contacts 150 and 152 may overlap the isolation region 120. The gate contact 142 and the gate contact 148 may be positioned over and overlap the edge portion 112 and the edge portion 114 of the active region 110, respectively. The gate contacts 142, 144, 146, 148, 150 and 152 may directly contact the silicide layer 140.

In one embodiment, the gate middle portion 130c is without an overlapping gate contact. In other words, every gate contact over the gate 130 is positioned over the gate end portion 130a or 130b of the gate 130.

Referring to FIGS. 1B and 1C, a metal line 162 may be arranged to extend over the gate contacts 142, 144 and 146 over the gate end portion 130a. In one embodiment, the metal line 162 overlaps the edge portion 112 of the active region 110 but is not arranged over or substantially over the inner portion 116 of the active region 110 so as to limit or reduce coupling with source/drain contacts 180 which may otherwise introduce additional capacitance to the device and impact device performance. A metal line 164 may be arranged to extend over the gate contacts 148, 150 and 152 over the gate end portion 130b. Similarly, the metal line 164 overlaps the edge portion 114 of the active region 110 but is not arranged over or substantially over the inner portion 116 of the active region 110 so as to limit or reduce coupling with source/drain contacts 180 which may otherwise introduce additional capacitance to the device and impact device performance. The metal line 162 and the metal line 164 may be metal layers arranged in a same metal level, such as a first metal level M1. The metal line 162 and the metal line 164 may be spaced apart from each other, for example, by dielectric material.

The structure 100 may further includes source/drain contacts 180 over the active region 110. The gate contacts, such as gate contacts 142, 144, 146, 148, 150 and 152, source/drain contacts may be formed of a metallic material, such as tungsten. The metal lines, such as metal line 162 and 164, may be formed of a metallic material, such as copper, copper alloy, aluminum or a combination thereof. Other suitable types of metal, alloys or conductive materials may also be useful.

Referring to FIGS. 1C and 1D, a dielectric layer 170 may be arranged over the gate 130 and the silicide layer 140. The dielectric layer 170 may surround the gate contacts 142, 144, 146, 148, 150 and 152. The dielectric layer 170 may be formed of a dielectric material, such as silicon oxide, silicon nitride, low-k dielectric (e.g., SiCOH) in the back-end-of-line (BEOL) process. In some embodiments, an etch stop layer, such as silicon nitride, may be arranged over the gate 130 and the silicide layer 140 and the dielectric layer 170 may be arranged over the etch stop layer (not shown).

In some embodiments, the breakage of the silicide layer 140 at or around the step profile may result in device performance issues, such as low Fmax for the transistor. Various embodiments as described provide a gate contact 142 and/or gate contact 148 which overlap the active region 110 in addition to gate contact(s) which overlap the isolation region 120 (e.g., gate contacts 144, 146, 150, 152. Accordingly, various embodiments advantageously provide a new or additional current path (e.g., via the gate contact 142 and/or gate contact 148) between the metal line 162 and/or metal line 164 in the first metal level and gate 130, for example, in the case where silicide layer breakage is present, thus reducing or eliminating the impact of the breakage of the silicide layer 140 to the device performance. An input signal may travel to the gate 130 through the gate contact 142 and/or gate contact 148 in addition to gate contact(s) over the isolation region 120 (e.g., gate contacts 144, 146, 150, 152). Various embodiments provide a structure which may overcome the defective issue (e.g., breakage of silicide layer due to the step height of the active region) in a die. Further, the issue of Fmax variability may be reduced or eliminated, for example for structures with regions having different topography (e.g., surfaces with different heights.

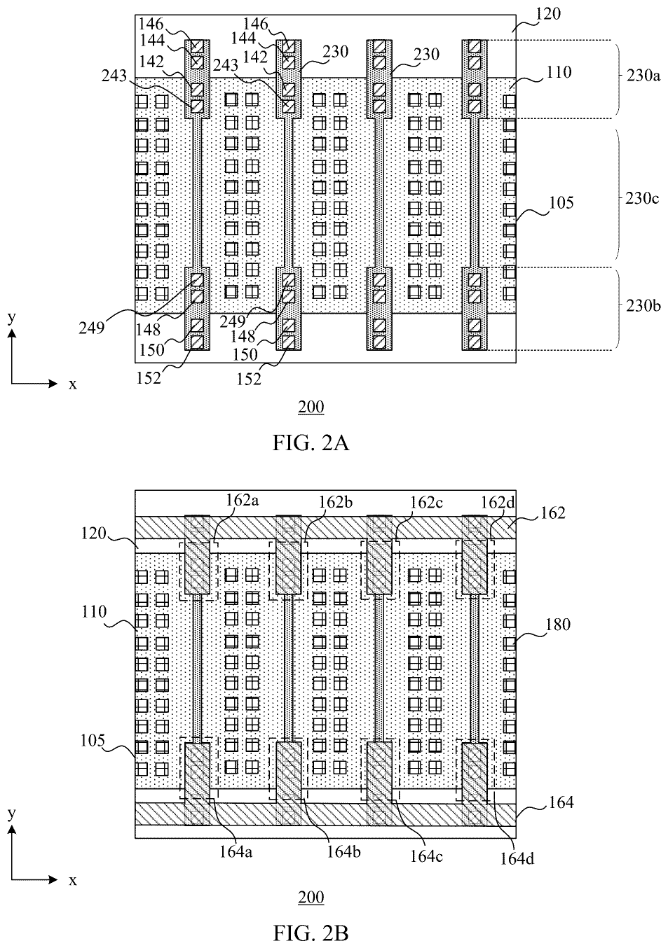

FIGS. 2A-2B illustrate top views of an embodiment of a structure 200. The structure 200, for example, is similar to the structure 100 described in FIGS. 1A-1D, but may include an array of gates 230. Each gate 230 may include gate end portions 230a and 230b, and a gate middle portion 230c between the gate end portions 230a and 230b. Similar to the gate 130 of the structure 100, the gate end portions 230a and 230b of each gate 230 are wider than the gate middle portion 230c so as to allow gate contacts to land on the gate end portions 230a and 230b, without increasing the width of the gate across the entire length of the gate 230. The gate end portions 230a and 230b represent a small fraction of the gate length of each gate 230 over the active region 110. In one embodiment, gate contacts 142, 144, 146 and 243 may be positioned over the gate end portion 230a, and gate contacts 148, 150, 152 and 249 may be positioned over the gate end portion 230b of each gate 230. The gate contacts 142 and 243 over the gate end portions 230a may overlap the active region 110, while the gate contacts 144 and 146 may overlap the isolation region 120. The gate contacts 148 and 249 over the gate end portion 230b may overlap the active region 110, while the gate contacts 150 and 152 may overlap the isolation region 120. The gate contacts 142 and 243 and the gate contacts 148 and 249 may be positioned over and overlap the edge portions of the active region 110. The gate contacts 142, 144, 146, 148, 150, 152, 243 and 239 may directly contact the underlying silicide layer.

In one embodiment, the metal line 162 may extend over the gate contacts 142, 144, 146 and 243 over each gate 230. The metal line 162 overlaps the gates 230 but does not run across an entire length of the gates 230. For example, the metal line 162 may overlap the gate end portions 230a but does not overlap or substantially overlap the gate middle portions 230c of the gates 230, as illustrated in FIG. 2B. In one embodiment, the metal line 162 may have a comb shape with a plurality of finger portions. For example, the metal line 162 may have a first finger portion 162a extending over the gate contacts 142 and 243 over a first gate of the array of gates 230, a second finger portion 162b extending over the gate contacts 142 and 243 over a second gate of the array of gates 230, a third finger portion 162c extending over the gate contacts 142 and 243 over a third gate of the array of gates 230, and a fourth finger portion 162d extending over the gate contacts 142 and 243 over a fourth gate of the array of gates 230. The first finger portion 162a, the second finger portion 162b, the third finger portion 162c and the fourth finger portion 162d may be in the same metal level and may be laterally spaced apart from each other.

The metal line 164 may extend over the gate contacts 148, 150, 152 and 249 over each gate 230. Similarly, the metal line 164 overlaps the gates 230 but does not run across an entire length of the gates 230. The metal line 164 may overlap the gate end portions 230b but does not overlap or substantially overlap the gate middle portions 230c of the gates 230. In one embodiment, the metal line 164 may have a comb shape with a plurality of finger portions. For example, the metal line 164 may have a first finger portion 164a extending over the gate contacts 148 and 249 over the first gate of the array of gates 230, a second finger portion 164b extending over the gate contacts 148 and 249 over the second gate of the array of gates 230, a third finger portion 164c extending over the gate contacts 148 and 249 over the third gate of the array of gates 230, and a fourth finger portion 164d extending over the gate contacts 148 and 249 over the fourth gate of the array of gates 230. The first finger portion 164a, the second finger portion 164b, the third finger portion 164c and the fourth finger portion 164d may be in the same metal level and may be laterally spaced apart from each other.

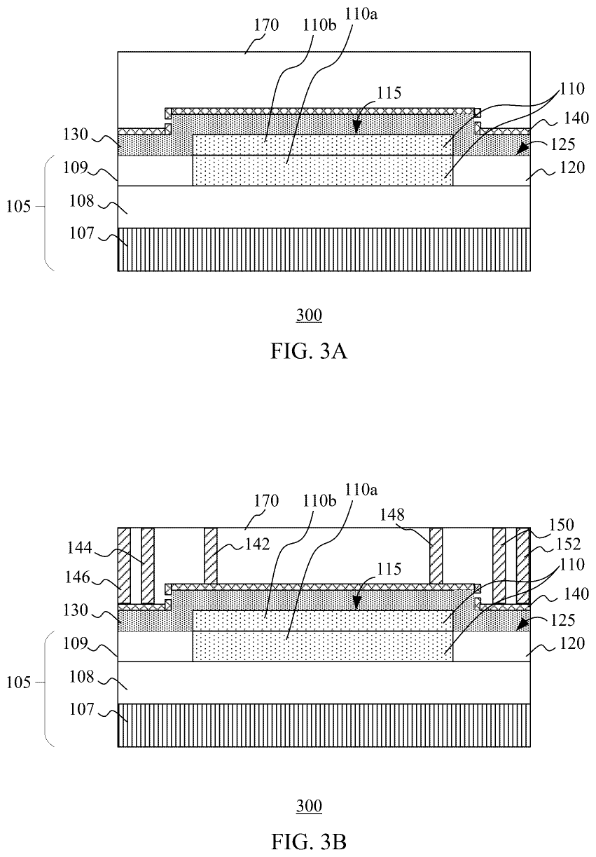

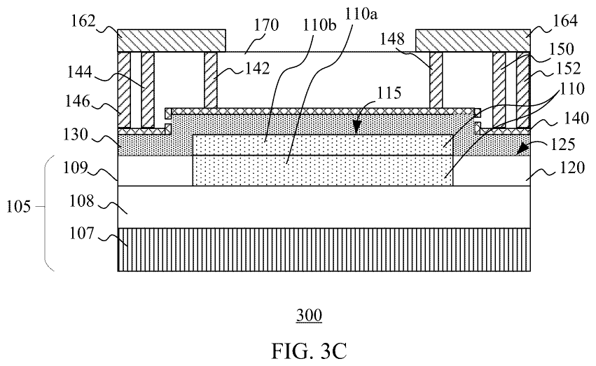

FIGS. 3A-3C show cross-sectional views of a process 300 for forming a structure. The structure, for example, is similar to that described in FIGS. 1A-1D and 2A-2B. As such, common elements may not be described or described in detail. For example, FIGS. 3A-3C illustrate side views of the structure which may taken along line A-A′ in FIG. 1B. The structure may be at a stage after formation of the gate 130 and silicide layer 140 over the active region 110 and over the isolation region 120 in the substrate 105. For example, the gate 130 may be formed by depositing a layer of gate material such as doped polysilicon over the active region 110 and the isolation region 120, and patterning the layer of gate material by lithography and etching processes to form the gate 130 having gate end portions, and a gate middle portion between the gate end portions (not shown). The silicide layer 140 may be formed by depositing a layer of metallic material directly on the gate 130, such as titanium, cobalt, nickel or tungsten, and performing an anneal process to form a metal-semiconductor alloy with the semiconductor material of the gate 130 or silicide layer 140. Untreated portions of the metallic material may be removed selective to the silicide layer 140, for example, by a wet etch.

Referring to FIG. 3A, dielectric layer 170 may be formed over substrate 105, for example, by chemical vapor deposition. A planarization process, such as chemical mechanical polishing, may be performed to provide a substantially planar top surface of the dielectric layer 170. The dielectric layer 170 may be part of a metallization structure, which may include interconnects disposed in a dielectric formed in a BEOL process. Referring to FIG. 3B, gate contacts 142, 144, 146, 148, 150 and 152 may be formed in the dielectric layer 170 and over the gate 130. For example, openings may be formed in the dielectric layer 170 by lithography and etching processes to expose portions of the silicide layer 140, contact liner may be deposited into the openings, a conductive material, such as tungsten, may be deposited into the openings to fill the opening, and a planarization process such as chemical mechanical polishing may be performed to form the gate contacts 142, 144, 146, 148, 150 and 152.

Referring to FIG. 3C, metal lines 162 and 164 may be formed over the gate contacts. The metal lines may be formed to extend over the gate contacts 142, 144 and 146, and the metal line 164 may be formed to extend over the gate contacts 148, 150 and 152. The metal lines 162 and 164 may be formed such that they overlap the gate end portions of the gate 130 but does not run across an entire length of the gate 130. For example, further dielectric material may be deposited over the substrate 105 and the dielectric layer 170 to form a further dielectric layer (not shown). Trenches for the metal lines may be formed in the further dielectric layer, for example, by lithography and etching processes. Conductive material may be deposited into the trenches and a planarization process, such as CMP, may be performed to remove excess conductive material, forming the metal lines 162 and 164.

The process 300 may continue with forming additional interconnects in the BEOL metallization structure.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A semiconductor structure, comprising:
an active region and an isolation region adjacent to the active region;
a gate arranged over the active region and the isolation region;
a first gate contact and a second gate contact over the gate, wherein the first gate contact overlaps the active region and the second gate contact overlaps the isolation region; and
a metal line extending over the first gate contact and the second gate contact.

2. The semiconductor structure of claim 1, wherein the active region has an inner portion between a first edge portion and a second edge portion of the active region, and the first gate contact overlaps the first edge portion of the active region.

3. The semiconductor structure of claim 2, wherein the gate comprises a first gate portion having a first gate width and overlapping the first edge portion of the active region, and a second gate portion having a second gate width and overlapping the inner portion of the active region, wherein the first gate width is greater than the second gate width.

4. The semiconductor structure of claim 3, wherein the second gate portion is without an overlapping gate contact.

5. The semiconductor structure of claim 1, wherein the gate has a gate middle portion between a first gate end portion and a second gate end portion of the gate, the first and second gate end portions of the gate are wider than the gate middle portion.

6. The semiconductor structure of claim 5, wherein the first and second gate contacts overlap the first gate end portion of the gate.

7. The semiconductor structure of claim 6, further comprising a third gate contact and a fourth gate contact over the second gate end portion of the gate, the third gate contact overlaps the active region and the fourth gate contact overlaps the isolation region.

8. The semiconductor structure of claim 7, further comprising a second metal line extending over the third gate contact and the fourth gate contact.

9. The semiconductor structure of claim 6, further comprising a third gate contact over the first gate end portion of the gate, wherein the third gate contact overlaps the active region.

10. The semiconductor structure of claim 5, wherein the gate middle portion of the gate is without an overlapping gate contact.

11. The semiconductor structure of claim 1, wherein the active region comprises a portion disposed within a substrate, and further comprising a raised active region portion directly over the portion disposed within the substrate.

12. The semiconductor structure of claim 11, wherein a portion of the gate is conformal to a top surface of a raised active region portion and another portion of the gate is conformal to a top surface of the isolation region.

13. The semiconductor structure of claim 12, further comprising a silicide layer over the gate, wherein the first gate contact and the second gate contact directly contact the silicide layer.

14. The semiconductor structure of claim 1, wherein the isolation region surrounds the active region.

15. The semiconductor structure of claim 1, further comprising:
a second gate arranged over the active region and the isolation region; and
a third gate contact and a fourth gate contact over the second gate, wherein the third gate contact overlaps the active region and the fourth gate contact overlaps the isolation region, wherein the metal line further extends over the third gate contact and the fourth gate contact.

16. The semiconductor structure of claim 15, wherein a portion of the metal line extending over the first gate contact is a first finger portion of the metal line, and a further portion of the metal line extending over the third gate contact is a second finger portion of the metal line, wherein the second finger portion is laterally spaced apart from the first finger portion.

17. A method, comprising:
forming a gate over an active region and an isolation region;
forming a first gate contact and a second gate contact over the gate, wherein the first gate contact overlaps the active region and the second gate contact overlaps the isolation region; and
forming a metal line over the first gate contact and the second gate contact.

18. The method of claim 17, wherein the active region has an inner portion between a first edge portion and a second edge portion of the active region, and the first gate contact overlaps the first edge portion of the active region.

19. The method of claim 18, wherein the gate comprises a first gate portion overlapping the first edge portion of the active region and having a first width, and a second gate portion overlapping the inner portion of the active region and having a second width, wherein the first width is greater than the second width.

20. The method of claim 19, wherein the gate further comprises a third gate portion overlapping the second edge portion of the active region and having the first width, and further comprising forming a third gate contact and a fourth gate contact over the third gate portion, the third gate contact overlaps the active region and the fourth gate contact overlaps the isolation region.
